(19) United States
(12) Patent Application Publication
(10) Pub. No.: US 2024/0194484 A1
(43) Pub. Date: Jun. 13, 2024

(54) DESIGN, CONTROL, AND OPTIMIZATION OF PHOTOSENSITIVITY MODULATION ALONG PHOTORESIST FILM DEPTH

(71) Applicant: Applied Materials, Inc., Santa Clara, CA (US)

(72) Inventors: RUIYING HAO, San Jose, CA (US); PAOLA DE CECCO, Salinas, CA (US); MADHUR SACHAN, Belmont, CA (US); KWANGDUK D. LEE, Redwood City, CA (US); MARTHA SANCHEZ, Menlo Park, CA (US); LUISA BOZANO, Los Altos Hills, CA (US)

(21) Appl. No.: 18/379,102

(22) Filed: Oct. 11, 2023

Related U.S. Application Data
(60) Provisional application No. 63/432,323, filed on Dec. 13, 2022.

(51) Int. Cl. H01L 21/033

(52) U.S. Cl. CPC H01L 21/0332; G03F 7/094

(57) ABSTRACT

Embodiments disclosed herein include a method for forming a photoresist stack. In an embodiment, the method comprises forming a first photoresist layer over a substrate, where the first photoresist layer is formed with a first dry deposition process, and forming a second photoresist layer over the first photoresist layer, where the second photoresist layer is formed with a second dry deposition process that is different than the first deposition process.

### CROSS-REFERENCE TO RELATED APPLICATIONS

This application claims the benefit of U.S. Provisional Application No. 63/432,323, filed on Dec. 13, 2022, the entire contents of which are hereby incorporated by reference herein.

### BACKGROUND

### 1) Field

Embodiments of the present disclosure pertain to the field of semiconductor processing and, in particular, to methods of depositing a photoresist in order to provide improved patterning and development.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method for forming a photoresist stack. In an embodiment, the method comprises forming a first photoresist layer over a substrate, where the first photoresist layer is formed with a first dry deposition process, and forming a second photoresist layer over the first photoresist layer, where the second photoresist layer is formed with a second dry deposition process that is different than the first deposition process.

Embodiments disclosed herein further comprise a method of patterning a substrate. In an embodiment, the method comprises depositing a first photoresist layer over the substrate, depositing a second photoresist layer over the first photoresist layer, where a cross-linking efficiency is different between the first photoresist layer and the second photoresist layer, exposing the first photoresist layer and the second photoresist layer to electromagnetic radiation, developing the first photoresist layer and the second photoresist layer to provide a patterned photoresist stack, and transferring a pattern of the patterned photoresist stack into the substrate.

Embodiments disclosed herein further comprise a photoresist stack. In an embodiment, the photoresist stack comprises a first photoresist layer with a first thickness, where the first photoresist layer comprises a first cross-linking efficiency, and a second photoresist layer over the first photoresist layer, where the second photoresist layer comprises a second thickness that is greater than the first thickness and a second cross-linking efficiency that is different than the first cross-linking efficiency.

### BRIEF DESCRIPTION OF THE DRAWINGS

FIG. 1A is a cross-sectional illustration of a photoresist disposed over a substrate, in accordance with an embodiment.

FIG. 1B is a cross-sectional illustration of the photoresist being exposed through a mask, in accordance with an embodiment.

FIG. 1C is a cross-sectional illustration of the photoresist after a developing process, in accordance with an embodiment.

FIG. 2A is a cross-sectional illustration of a photoresist disposed over a substrate, in accordance with an embodiment.

FIG. 2B is a cross-sectional illustration of the photoresist being exposed through a mask, in accordance with an embodiment.

FIG. 2C is a cross-sectional illustration of the photoresist after a developing process that results in undercutting, in accordance with an embodiment.

FIG. 3A is a cross-sectional illustration of a first layer of photoresist over a substrate, in accordance with an embodiment.

FIG. 3B is a cross-sectional illustration of a second layer of photoresist over the first layer of photoresist, in accordance with an embodiment.

FIG. 3C is a cross-sectional illustration of the photoresist layers being exposed through a mask, in accordance with an embodiment.

FIG. 3D is a cross-sectional illustration of the photoresist stack after a developing process, in accordance with an embodiment.

FIG. 3E is a cross-sectional illustration of the pattern of the photoresist stack being transferred into the underlying substrate, in accordance with an embodiment.

FIG. 4 is a process flow diagram depicting a process for forming and patterning a photoresist stack with a first photoresist layer and a second photoresist layer, in accordance with an embodiment.

FIG. 5 illustrates a block diagram of an exemplary computer system, in accordance with an embodiment of the present disclosure.

### DETAILED DESCRIPTION

Methods of depositing a photoresist in order to provide improved patterning and development are described herein. In the following description, numerous specific details are set forth, such as thermal vapor phase processes and material regimes for developing photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Organic-inorganic hybrid materials (e.g., metal oxo materials systems) have been proposed as a material system for EUV lithography due to the increased sensitivity to EUV radiation. Such material systems typically comprise a metal (e.g., Sn, Hf, Zr, etc.), oxygen, and carbon. Metal oxo based organic-inorganic hybrid materials have also been shown to provide lower LER, LWR, and higher resolution, which are required characteristics for forming narrow features.

In a metal oxo photoresist system, exposure to EUV radiation results in crosslinking and the removal of carbon. The difference in the carbon percentage between the exposed regions and the unexposed regions is used as the solubility switch during developing. Particularly, the unexposed regions with the higher carbon content are preferentially etched by the developer solution in a negative tone develop. Though, it is to be appreciated that a positive tone develop may also be used in some embodiments.

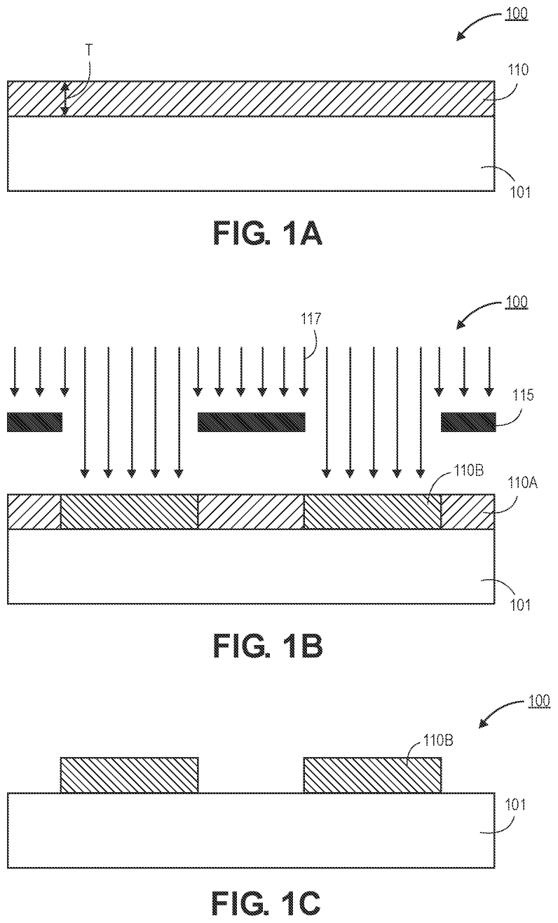

Despite the improvements in efficiency provided by metal oxo systems, exposure issues may still persist. Particularly, in thicker photoresist layers, there may be different degrees of cross-linking at different depths. That is, the portion of the photoresist closer to the surface of the underlying substrate may not be fully developed like the overlying portions of the photoresist. As such, relatively thin photoresist materials are generally needed. An example of such an embodiment is shown in FIG. 1A.

As shown in FIG. 1A, a device 100 includes a substrate 101 with a photoresist layer 110 provided over the substrate 101. The photoresist layer 110 may have a relatively small thickness T. For example, the thickness T may need to be approximately 10 nm or less in order to provide complete exposure through the entire thickness of the photoresist layer 110.

Referring now to FIG. 1B, a cross-sectional illustration of the device 100 during exposure to EUV radiation 117 is shown, in accordance with an embodiment. The EUV radiation 117 may pass through a mask 115 or otherwise be reflected towards specific locations on the photoresist layer 110. As shown, regions 110B of the photoresist layer 110 are exposed and regions 110A remain unexposed. The dose of the exposure may be sufficient to provide a transition in material properties through the entire thickness of the photoresist layer 110 in regions 110B.

Referring now to FIG. 1C, a cross-sectional illustration of the device 100 after a developing process is shown, in accordance with an embodiment. In an embodiment, the developing process may result in the unexposed regions 110A of the photoresist layer 110 being removed. Since the exposed regions 110B have material property changes through an entire thickness of the photoresist layer 110, the resulting structure may have substantially vertical sidewalls.

While such a photoresist system may be useful for some applications, the photoresist 110 still has limitations. Particularly, due to the low thickness T of the photoresist 110, there may be issues with etch selectivity. That is, during transfer of the pattern into the underlying substrate 101, the exposed regions 110B may also be etched (though at a slower rate). Since the exposed regions 110B are consumed, the depth of the etch into the substrate 101 is limited.

Accordingly, it has been proposed to use thicker photoresist layers in order to provide more margin for etch selectivity. By providing a thicker photoresist layer, there is more margin to account for less than ideal etch selectivities. However, the increased thickness of the photoresist layer may result in exposed regions that are not fully transformed by the EUV radiation. Particularly, the bottom portion of the photoresist layer near the substrate may not be fully converted. This can result in undercutting or other defects that negatively impact pattern transfer into the underlying substrate.

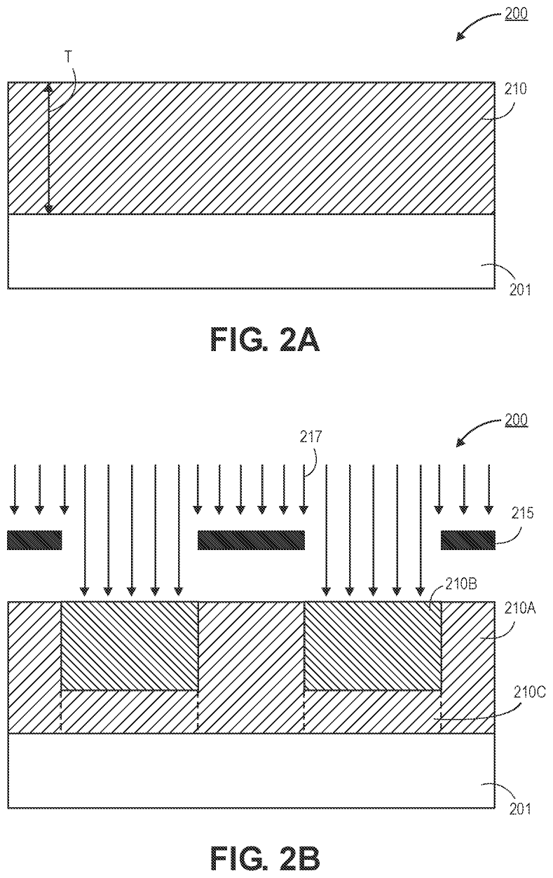

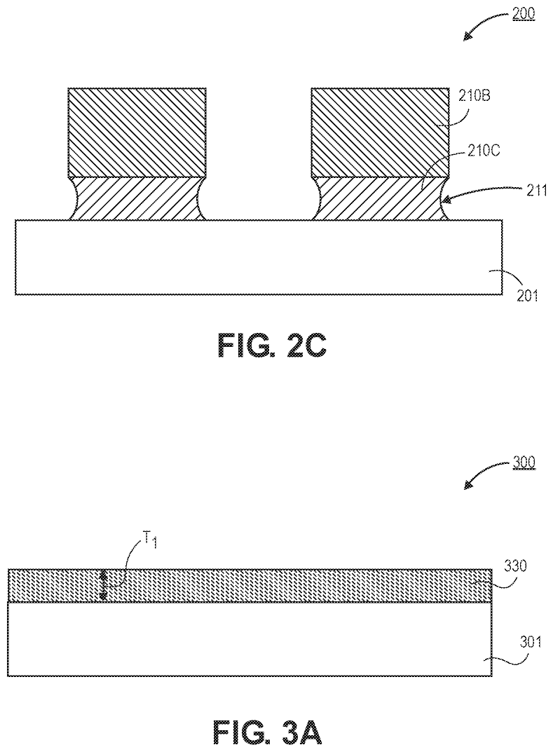

An example of such a situation is shown in FIGS. 2A-2C. As shown in FIG. 2A, a device 200 with a photoresist layer 210 over an underlying substrate 201 is provided. The photoresist layer 210 may have a thickness T that is greater than the thickness T shown in FIG. 1A. For example, the thickness T may be approximately 20 nm thick or greater. In an embodiment, the photoresist layer 210 may comprise a metal oxo resist material, or any other chemically amplified resist (CAR) system.

Referring ow to FIG. 2B, a cross-sectional illustration of the device 200 during exposure to EUV radiation 217 is shown, in accordance with an embodiment. The EUV radiation 217 may pass through a mask 215 or otherwise be reflected towards specific locations on the photoresist layer 210. As shown, regions 210B of the photoresist layer 210 are exposed and regions 210A remain unexposed. However, the exposure to radiation 217 may not fully penetrate through a thickness of the photoresist layer 210. For example, regions 210C below regions 210B may not be transformed like the layer 210B.

Referring now to FIG. 2C, a cross-sectional illustration of the device 200 after a developing process is shown, in accordance with an embodiment. As shown, the regions 210A are removed. However, since the bottom regions 210C are also only at least partially converted into a non-dissolvable material, portions of the regions 210C may etch laterally. This can produce undercuts 211. The undercuts 211 may negatively impact the pattern transfer into the underlying substrate 201.

Accordingly, embodiments disclosed herein include a two part photoresist system. The two part system may include a first layer and a second layer. The first layer directly on the substrate may be tuned fully cross-link at a lower dosage of EUV radiation than the second layer, which is over the first layer. Therefore, even when the first layer does not receive as high of a dose as the second layer, both layers may be fully transformed by the EUV radiation. As such, high quality pattern transfer can occur. Further, since the combine thickness of the two part photoresist system can be larger, issues with etch selectivity are mitigated.

In an embodiment, the two part photoresist system may be provided by modifying the deposition processes for the first layer and the second layer. For example, the deposition process may have different deposition temperatures, different deposition rates, or be deposited with different deposition regimes (e.g., chemical vapor deposition (CVD), atomic layer deposition (ALD), sputtering, condensation, etc.). That is, the first layer and the second layer may be substantially the same composition, but are deposited with different processes. Though in some embodiments, different material compositions may be used for the first layer and the second layer. Additionally, while referred to as being a first layer and a second layer, it is to be appreciated that a plurality of layers (e.g., three or more) may be used, or even a gradient of various deposition conditions may be applied to the photoresist system.

The ability to fine tune the deposition conditions in the photoresist layer is enabled through the use of a dry deposition processes. Previously, wet deposition processes (e.g., spin coating) were used in order to form metal oxo photoresist layers. Wet processes have a variety of different issues. One of the issues is that composition uniformity (or controlled non-uniformity) is difficult, if not impossible, to obtain. However, with dry deposition processes there are many different control knobs that can be modified in order to change the performance of the photoresist system. For example, deposition temperature, flow rate of precursor gasses, pressure, and the like can be used to modify the performance of the photoresist system.

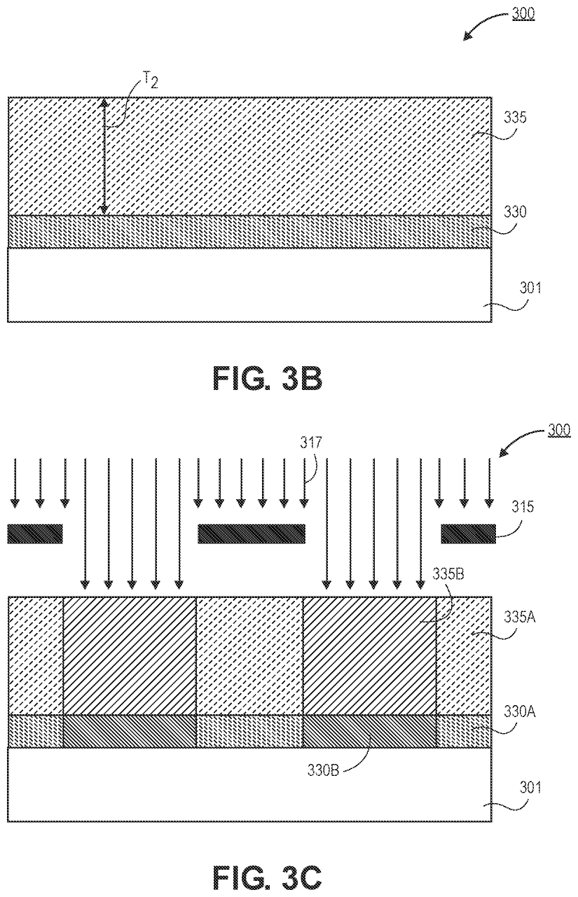

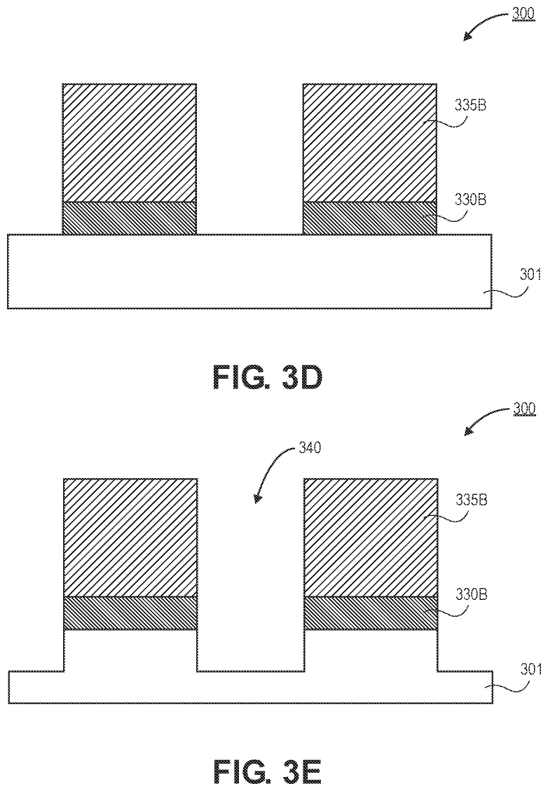

Referring now to FIGS. 3A-3E, a series of cross-sectional illustrations of a process for forming a multi-layer photoresist system, and transferring a pattern into an underlying substrate is shown, in accordance with an embodiment. In an embodiment, the multi-layer photoresist system may be tuned in order to provide a non-uniform cross-linking efficiency (or dose to size) at different depths within the photoresist system. As such, thicker photoresist systems can be provided while still maintaining high quality pattern transfer into the underlying substrate. That is, the photoresist system may provide excellent LER, LWR, resolution, and the like.

Referring now to FIG. 3A, a cross-sectional illustration of a device 300 is shown, in accordance with an embodiment. In an embodiment, the device 300 may include a substrate 301 and a first photoresist layer 330. The substrate 301 may be any semiconductor substrate (e.g., silicon) or any other layer that is commonly patterned in semiconductor manufacturing environments (e.g., metal layers, dielectric layers, insulating layers, and the like). The substrate 301 may also include hardmask layers, underlayers, anti-reflective coatings (ARCs), or any other layer or layers that may benefit pattern transfer operations. The first photoresist layer 330 may include a first thickness T₁. The first thickness T₁ may be up to approximately 10 nm. In a particular embodiment, the first thickness T₁ is approximately 5 nm or less.

In an embodiment, the first photoresist layer 330 may be a metal oxo photoresist material, or any other CAR material that is suitable for EUV, DUV, or UV exposure. In a particular embodiment, the first photoresist layer 330 may be a tin based metal oxo material. Though, other metals may also be used in some embodiments. For example, the metal may include Zr, Al, Hf, Cr, Ta, Ru, Mo, Te, Ti, Zn, etc. In a particular embodiment, the first photoresist layer 330 comprises SnOC. In a more general sense, the first photoresist layer 330 may comprise a structure of the form (RₐM)_{b}O_{c}(OH)_{d} where R is a ligand and M is a metal. In an embodiment, a is less than or equal to b, and b is between 2 and 125. In an embodiment, c+d is less than or equal to b, and x is 2 to 8.

In an embodiment, the first photoresist layer 330 may be tuned so as to enable conversion of material properties with a relatively low dose of EUV radiation. The low dose property of the first photoresist layer 330 may be obtained through controlling the deposition parameters used to form the first photoresist layer 330. In some embodiments, the deposition temperature may be controlled in order to modulate the dose to size or cross-linking efficiency. For example, a relatively low deposition temperature may be used in some embodiments. Particularly, the deposition temperature for the first photoresist layer 330 may be approximately 50 degrees Celsius or less. In one embodiment, the deposition temperature may be approximately 40 degrees Celsius or less.

In an embodiment, the cross-linking efficiency may also be modulated by controlling a deposition rate of the first photoresist layer 330. Relatively faster deposition rates may be used in order to allow for higher cross-linking efficiency. The deposition rate may be modulated by changing the flow rate of the precursor gasses used to form the photoresist layer 330.

While the examples of deposition temperature and deposition rate are provided as specific examples of control knobs that can be modulated to increase cross-linking efficiency of the first photoresist layer 330, it is to be appreciated that embodiments are not limited to such configurations. For example, different deposition techniques may also be used. For example, a CVD or ALD process may be used to form the first photoresist layer 330 and a different deposition process may be used to deposit the subsequent photoresist layers. Additionally, a single control knob may be modulated, or multiple control knobs may be modulated. For example, the first photoresist layer 330 may be deposited with both a low deposition temperature and a faster deposition rate.

Referring now to FIG. 3B, a cross-sectional illustration of a device 300 is shown, in accordance with an embodiment. In an embodiment, the device 300 may be similar to the device 300 in FIG. 3A with the addition of a second photoresist layer 335. The second photoresist layer 335 may have a second thickness T₂. The second thickness T₂ may be greater than the first thickness T₁. For example, the second thickness T₂ may be up to approximately 30 nm, up to approximately 20 nm, or up to approximately 10 nm.

In an embodiment, the second photoresist layer 335 may have a different cross-linking efficiency that the first photoresist layer 330. The second photoresist layer 335 may have a cross-linking efficiency that is lower than the cross-linking efficiency of the first photoresist layer 335. That is, a larger dose is needed to convert the second photoresist layer 335 than the first photoresist layer 330. In an embodiment, the first photoresist layer 330 and the second photoresist layer 335 may be compositionally similar. For example, the atomic composition of the first photoresist layer 330 may be substantially similar to the atomic composition of the second photoresist layer 335. Though, in some embodiments, there may be compositional variation between the first photoresist layer 330 and the second photoresist layer 335.

In an embodiment, the cross-linking efficiency of the second photoresist layer 335 may be set by deposition temperature. For example, a deposition temperature of the second photoresist layer 335 may be higher than a deposition temperature of the first photoresist layer 330. For example, a deposition temperature of the second photoresist layer 335 may be approximately 50 degrees Celsius or greater, approximately 90 degrees Celsius or greater, or approximately 100 degrees Celsius or greater.

In another embodiment, the cross-linking efficiency of the second photoresist layer 335 may be set by a deposition rate. For example, a deposition rate of the second photoresist layer 335 may be slower than a deposition rate of the first photoresist layer 330. The deposition rate of the second photoresist layer 335 may be reduced by decreasing the flow rate of precursor gasses compared to the flow rate used to form the first photoresist layer 330.

While deposition temperature and deposition rate are explicitly given as two different control knobs that can be modulated, it is to be appreciated that many different control knobs can be used to modulate cross-linking efficiency. In one embodiment, the first photoresist layer 330 may be deposited with one of CVD or ALD, and the second photoresist layer 335 may be deposited with the other of CVD or ALD.

In the embodiments described in FIGS. 3A and 3B, a pair of photoresist layers 330 and 335 are shown. However, it is to be appreciated that any number of photoresist layers may be included in the device 300. For example, the cross-linking efficiency may increase as the depth into the stack increases. That is, the photoresist closer to the substrate 301 will have a higher cross-linking efficiency than photoresist further from the substrate 301. While discrete layers (e.g., first photoresist layer 330 and second photoresist layer 335) are shown, it is to be appreciated that a gradient type photoresist stack may also be used. For example, the deposition temperature may start at a relatively low temperature and increase in temperature with subsequent deposition. In another embodiment, the deposition rate may start high and reduce as the thickness of the photoresist layer increases.

Referring now to FIG. 3C, a cross-sectional illustration of the device 300 during an EUV exposure process is shown, in accordance with an embodiment. The EUV radiation 317 may pass through a mask 315 or otherwise be reflected towards specific locations on the photoresist layers 330 and 335. As shown, the exposed regions 330B and 335B are modified compared to the unexposed regions 330A and 335A. Despite being buried deep within the stack, the first photoresist layer 330 still can undergo full conversion. This is because the first photoresist layer 330 has a higher cross-linking efficiency. That is, the exposed region 330B will undergo complete transformation even when receiving a smaller dose of EUV radiation 317.

Referring now to FIG. 3D, a cross-sectional illustration of the device 300 after the photoresist layers 330 and 335 are developed is shown, in accordance with an embodiment. In an embodiment, the developing process may be done through the exposure to a wet etching chemistry. In other embodiments, a dry etching chemistry may be used to develop the photoresist layers 330 and 335. In an embodiment, the unexposed regions 330A and 335A are removed with the developing chemistry. However, in other embodiments, the unexposed regions 330A and 335A may remain and the exposed regions 330B and 335B may be removed.

As shown, the developed photoresist layers 330 and 335 have relatively vertical sidewalls. Since the bottom first photoresist layer 330B is fully converted, there is no undercut etching, as shown in examples provided above. As such, pattern transfer into the underlying substrate is more accurate, may result in improved LER or LWR, improved resolution, improved critical dimension (CD), and other improved patterning properties.

Referring now to FIG. 3E, a cross-sectional illustration of the device 300 after a pattern transferring process is shown, in accordance with an embodiment. As shown, the pattern of the photoresist layers 330B and 335B may be transferred into the substrate 301 in order to form trenches 340. While referred to as trenches 340, it is to be appreciated that the etched features in the substrate 301 may be holes or any other subtractive shape. It is to be appreciated that the formation of the trenches 340 can be made with an etching process that has sub-optimal etch selectivity. Particularly, since the total thickness of the photoresist structure can be increased, there does not need to be a high etch selectivity. That is, the increased thickness of the photoresist structure permits substantial etching of the photoresist structure without negatively impacting the resolution or other patterning parameters.

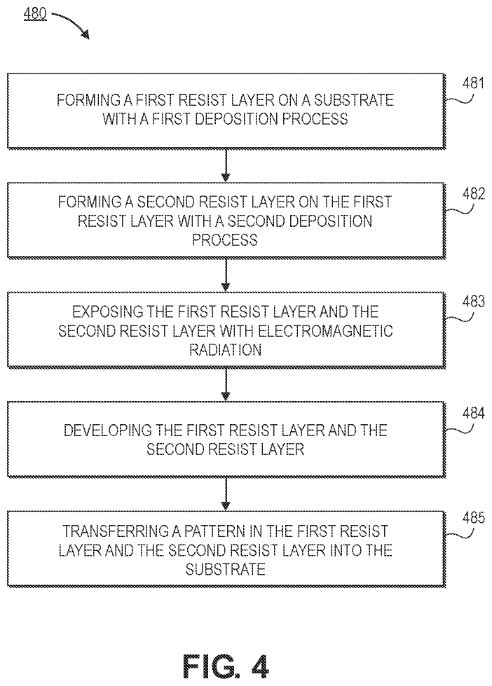

Referring now to FIG. 4, a process flow diagram depicting a process 480 for patterning a substrate is shown, in accordance with an embodiment. In an embodiment, the process 480 includes the use of a photoresist structure that has a non-uniform cross-linking efficiency through a thickness of the photoresist structure. For example, the photoresist structure may include a first layer with a high cross-linking efficiency and a second layer with a lower cross-linking efficiency. As such, the first layer is fully converted with a lower dose compared to the second layer.

In an embodiment, the process 480 may begin with operation 481, which comprises forming a first resist layer on a substrate with a first deposition process. In an embodiment, the first resist layer may be an EUV resist or a CAR. The first resist layer may be formed to have a relatively high cross-linking efficiency. In an embodiment, the high cross-linking efficiency may be provided by having a low deposition temperature and/or a high deposition rate. Though, other control knobs may also be used in order to modify the cross-linking efficiency of the first resist layer. In an embodiment, the first resist layer may have a thickness that is approximately 10 nm or less, or approximately 5 nm or less.

In an embodiment, process 480 may continue with operation 482, which comprises forming a second resist layer on the first resist layer with a second deposition process. In an embodiment, the first resist layer and the second resist layer may both have substantially the same material composition. The difference between the first resist layer and the second resist layer may be the result of the differences between the first deposition process and the second deposition process. For example, the second deposition process may result in the second resist layer having a lower cross-linking efficiency. The second deposition process may have a higher deposition temperature and/or a lower deposition rate than the first resist layer. Additionally, the second resist layer may have a thickness that is greater than the first resist layer. For example, the second resist layer may have a thickness of 30 nm or less, 20 nm or less, or 10 nm or less.

In the particular embodiment described with respect to process 480, a pair of resist layers are included. However, it is to be appreciated that a plurality of different resist layers may be provided in some embodiments. In such an embodiment, the cross-linking efficiency increases with depth into the resist stack. Additionally, while a resist stack with discrete layers is possible, it is to be appreciated that embodiments with a gradient type resist stack may also be used in some embodiments.

In an embodiment, process 480 may continue with operation 483, which comprises exposing the first resist layer and the second resist layer with electromagnetic radiation. In an embodiment, the electromagnetic radiation may be EUV, DUV, or UV radiation. The electromagnetic radiation may result in the cross-linking of the exposed portions of the first resist layer and the second resist layer. Particularly, since the first resist layer has a higher cross-linking efficiency, it is able to be fully cross-linked even though the dose that reaches the first layer may be smaller than the dose that is applied to the second resist layer.

In an embodiment, process 480 may continue with operation 484, which comprises developing the first resist layer and the second resist layer. The developing process may be a dry develop process, or exposure to a liquid developer chemistry. In an embodiment, the exposed regions of the first resist layer and the second resist layer may remain after developing. In other embodiments, the unexposed regions of the first resist layer and the second resist layer may remain after developing.

In an embodiment, process 480 may continue with operation 485, which comprises transferring a pattern in the first resist layer and the second resist layer into the substrate. The pattern transfer process may be implemented with any suitable etching chemistry. Since the second resist layer can be made thick, a total thickness of the resist stack is increased. This benefits the pattern transfer process since the etch selectivity between the resist stack and the underlying substrate does not need to be as high as if a thin resist layer is used.

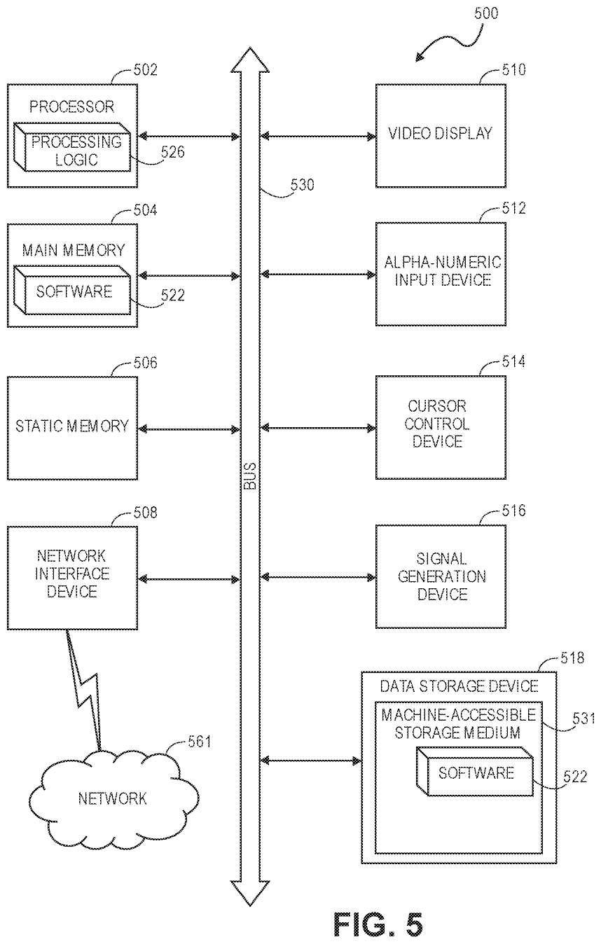

FIG. 5 illustrates a diagrammatic representation of a machine in the exemplary form of a computer system 500 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), MRAM, etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations described herein.

The computer system 500 may further include a network interface device 508. The computer system 500 also may include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 532 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of providing a photoresist system that includes a non-uniform cross-linking efficiency through a thickness of the photoresist system In an embodiment, the method includes forming a first photoresist layer with a first cross-linking efficiency, and forming a second photoresist layer with a second (lower) cross-linking efficiency over the first photoresist layer. In an embodiment, the first photoresist layer has a thickness that is less than a thickness of the second photoresist layer. The difference in cross-linking efficiency can be provided by changes to deposition rate, deposition temperature, deposition regimen (e.g., CVD, ALD, etc.), or any other control knob. Such a photoresist stack allows for complete cross-linking through the entire thickness of the photoresist stack and enables improved pattern transfer.

Thus, methods for forming a photoresist stack with non-uniform cross-linking efficiency have been disclosed.

What is claimed is:

1. A method for forming a photoresist stack, comprising:
forming a first photoresist layer over a substrate, wherein the first photoresist layer is formed with a first dry deposition process; and
forming a second photoresist layer over the first photoresist layer, wherein the second photoresist layer is formed with a second dry deposition process that is different than the first deposition process.

2. The method of claim 1, wherein a difference between the first dry deposition process and the second dry deposition process is a deposition temperature.

3. The method of claim 2, wherein the first dry deposition process has a first deposition temperature that is less than a second dry deposition temperature of the second deposition process.

4. The method of claim 3, wherein the first deposition temperature is 50 degrees Celsius or less, and the second deposition temperature is 50 degrees Celsius or greater.

5. The method of claim 1, wherein a difference between the first dry deposition process and the second dry deposition process is a deposition rate.

6. The method of claim 5, wherein a first deposition rate of the first photoresist layer is higher than a second deposition rate of the second photoresist layer.

7. The method of claim 6, wherein the first deposition rate and the second deposition rate are controlled by a flowrate of a precursor gas into a chamber.

8. The method of claim 1, wherein the first dry deposition process is an atomic layer deposition (ALD) process, and the second dry deposition process is a chemical vapor deposition (CVD) process.

9. The method of claim 1, wherein the first photoresist layer has a first thickness and the second photoresist layer has a second thickness, wherein the first thickness is smaller than the second thickness.

10. The method of claim 9, wherein the first thickness is up to 5 nm.

11. The method of claim 1, wherein the photoresist stack comprises a metal oxo photoresist material that is configured to be exposed with an extreme ultraviolet (EUV) radiation.

12. The method of claim 1, wherein the photoresist stack comprises a chemically amplified resist (CAR).

13. A method of patterning a substrate, comprising:
depositing a first photoresist layer over the substrate;
depositing a second photoresist layer over the first photoresist layer, wherein a cross-linking efficiency is different between the first photoresist layer and the second photoresist layer;
exposing the first photoresist layer and the second photoresist layer to electromagnetic radiation;
developing the first photoresist layer and the second photoresist layer to provide a patterned photoresist stack; and
transferring a pattern of the patterned photoresist stack into the substrate.

14. The method of claim 13, wherein the first photoresist layer is thinner than the second photoresist layer.

15. The method of claim 13, wherein the first photoresist layer is deposited with a first dry deposition process, and the second photoresist layer is deposited with a second dry deposition process.

16. The method of claim 15, wherein the first deposition process is different than the second deposition process in one or both of deposition temperature and deposition rate.

17. The method of claim 13, wherein the patterned photoresist stack comprises a metal oxo material.

18. The method of claim 13, wherein the patterned photoresist stack has substantially vertical sidewalls through an entire thickness of the photoresist stack.

19. A photoresist stack, comprising:
a first photoresist layer with a first thickness, wherein the first photoresist layer comprises a first cross-linking efficiency; and
a second photoresist layer over the first photoresist layer, wherein the second photoresist layer comprises a second thickness that is greater than the first thickness and a second cross-linking efficiency that is different than the first cross-linking efficiency.

20. The photoresist stack of claim 19, wherein the first photoresist layer and the second photoresist layer comprise a metal oxo material that is patternable with extreme ultraviolet (EUV) radiation.
